(19) United States
(12) Patent Application Publication
(10) Pub. No.: US 2025/0293649 A1
(43) Pub. Date: Sep. 18, 2025

(54) ADJUSTMENT CIRCUIT AND ADJUSTMENT METHOD USING THE SAME, CURRENT ADJUSTMENT CIRCUIT AND CURRENT ADJUSTMENT METHOD USING THE SAME, OPERATIONAL AMPLIFIER, AND OFFSET ADJUSTMENT METHOD

(71) Applicant: ROHM CO., LTD., KYOTO-SHI (JP)

(72) Inventor: Iori MIHARA, KYOTO-SHI (JP)

(21) Appl. No.: 19/074,944

(22) Filed: Mar. 10, 2025

(30) Foreign Application Priority Data
Mar. 12, 2024 (JP) 2024-038464

(51) Int. Cl. H03F 3/45

(52) U.S. Cl. CPC H03F 3/45475; H03F 2200/375

(57) ABSTRACT

An adjustment circuit is disposed between a first node and a second node. The adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected.

### CROSS REFERENCE TO RELATED APPLICATIONS

The present invention claims priority under 35 U.S.C. § 119 to Japanese Application No. 2024-038464, filed on Mar. 12, 2024, the entire contents of which being incorporated herein by reference.

### TECHNICAL FIELD

The present disclosure relates to an adjustment circuit, an adjustment method using the same, a current adjustment circuit, a current adjustment method using the same, an operational amplifier, and an offset adjustment method.

### BACKGROUND

Fuses are used to interrupt a circuit path by being provided in a circuit and disconnected as needed to achieve specific functions. For example, Patent Document 1 discloses an operational amplifier including a differential circuit that has the function of adjusting the input offset voltage by disconnecting a fuse.

### PRIOR ART DOCUMENT

### Patent Publication

[Patent document 1] Japan Patent Publication No. 2006-318337.

### BRIEF DESCRIPTION OF THE DRAWINGS

FIG. 1 is a schematic block diagram of an operational amplifier according to one embodiment of the present disclosure.

FIG. 2 is a circuit diagram of an input stage according to the same embodiment.

FIG. 3 is a circuit diagram of a current adjustment circuit according to the same embodiment.

FIG. 4 is a diagram showing an example layout of two fuses connected in series in a connection path.

FIG. 5 is a circuit diagram illustrating an example of an operation of a current adjustment circuit after a fuse is disconnected.

FIG. 6 is a diagram illustrating an amount by which an input offset voltage can be adjusted by each of a first current path, a second current path, a third current path, and a fourth current path sinking a current.

FIG. 7 is a diagram showing a layout of a fuse provided in a connection path according to a first modification.

FIG. 8 is a circuit diagram of a control circuit according to a second embodiment.

FIG. 9 is a circuit diagram of a current adjustment circuit according to a third embodiment.

FIG. 10 is a circuit diagram of a voltage generation circuit according to an application example.

### DETAILED DESCRIPTION OF THE EMBODIMENTS

### [Detailed Description]

### (Overview)

An overview of some exemplary embodiments of the present disclosure are illustrated. This overview serves as a preface to the detailed description that follows, is intended to provide a basic understanding of one or more embodiments by simplifying some concepts related to the embodiments and is not intended to limit the scope of the invention or disclosure. This overview is not intended to be a comprehensive summary of all possible embodiments, nor is it intended to identify all the essential elements of every embodiment or to delineate the scope of some or all aspects. For convenience, the term “one embodiment” may be used to refer to one embodiment (including examples and variations) or multiple embodiments (including examples and variations) disclosed in this specification.

An adjustment circuit according to one embodiment is disposed between a first node and a second node. The adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected.

According to this configuration, even if the disconnection of some of the disconnection target elements among the plurality of disconnection target elements fails, as long as at least one disconnection target element is disconnected, the adjustment circuit can be opened. Therefore, by disconnecting the disconnection target elements, it becomes possible to accurately adjust the connection state of the adjustment circuit and more reliably achieve the desired operation of the circuit.

In one embodiment, the plurality of disconnection target elements may each be formed of a fuse. The plurality of fuses may be disposed side by side in a width direction of the fuses.

In one embodiment, the adjustment circuit may be provided so that a voltage at the first node becomes a first voltage when none of the plurality of disconnection target elements are disconnected, and a voltage at the first node becomes a second voltage when at least one of the plurality of disconnection target elements is disconnected.

An adjustment circuit according to one embodiment is disposed between a first node and a second node. The adjustment circuit comprises a signal generation circuit and a plurality of disconnection target elements and is configured such that the signal generation circuit outputs a first voltage to the first node when none of the plurality of disconnection target elements is disconnected, and the signal generation circuit outputs a second voltage to the first node when at least one of the plurality of disconnection target elements is disconnected.

According to this configuration, even if the disconnection of some of the disconnection target elements among the plurality of disconnection target elements fails, as long as at least one disconnection target element is disconnected, the voltage output by the adjustment circuit can be adjusted to the desired voltage. Therefore, by disconnecting the disconnection target elements, it becomes possible to accurately adjust the generated signal and more reliably achieve the desired operation of the circuit.

In one embodiment, the signal generation circuit may be an OR circuit. The plurality of disconnection target elements may include a first disconnection target element and a second disconnection target element. The first disconnection target element may be disposed between a first input terminal of the OR circuit and the second node. The second disconnection target element may be disposed between a second input terminal of the OR circuit and the second node.

A current adjustment circuit according to one embodiment may adjust the amount of current flowing to an active load circuit, in which the current is generated by a current generation circuit. The current adjustment circuit may comprise a sink circuit which comprises a switching element and adjusts the current amount by sinking a current depending on whether the switching element is on or off from the current generation circuit, and a control circuit comprising the adjustment circuit. A voltage corresponding to the voltage at the first node may be input to an input terminal of the switching element. A predetermined voltage may be supplied to the second node. On/off of the switching element may be controlled depending on whether the voltage at the first node is the first voltage or the second voltage.

An operational amplifier according to one embodiment may include a current generation circuit and the current adjustment circuit. The current generation circuit may be a differential input pair comprising a first MOS transistor to which a first input voltage is input and a second MOS transistor to which a second input voltage is input. The sink circuit may adjust the amount of one of a first drain current and a second drain current flowing in the active load circuit by sinking one of the first drain current flowing in the first MOS transistor and the second drain current flowing in the second MOS transistor.

In one embodiment, the sink circuit may comprise two switching elements, one of which is a first switching element connected to a drain of the first MOS transistor and the other of which is a second switching element connected to a drain of the second MOS transistor. The control circuit may comprise a plurality of adjustment circuits including a first adjustment circuit and a second adjustment circuit. A voltage corresponding to a voltage at a first node of the first adjustment circuit may be input to an input terminal of the first switching element. A voltage corresponding to a voltage at a first node of the second adjustment circuit may be input to an input terminal of the second switching element. The sink circuit may sink the first drain current or the second drain current via a switching element that is turned on among the first switching element or the second switching element.

In one embodiment, the sink circuit may include a plurality of current paths with different current-sinking capacities, each provided with a switching element. A voltage corresponding to a voltage at a first node of the adjustment circuit may be input to an input terminal of a switching element provided in any one of the plurality of current paths. The sink circuit may be configured to sink one of the first drain current and the second drain current via a current path in which the switching element is turned on is provided among the plurality of current paths.

In one embodiment, the switching elements may have priorities defined based on the current-sinking capabilities of corresponding current paths and standard deviations of input offset voltages of the operational amplifier. A voltage corresponding to a voltage at a first node of the adjustment circuit may be input to the input terminal of the switching element with the highest priority among the plurality of switching elements.

An adjustment method according to one embodiment is a method using an adjustment circuit disposed between a first node and a second node. The adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected. The adjustment method includes a disconnection step that disconnects at least one of the plurality of disconnection target elements.

According to this configuration, even if the disconnection of some of the disconnection target elements among the plurality of disconnection target elements fails, as long as at least one disconnection target element is disconnected, the adjustment circuit can be opened. Therefore, by disconnecting the disconnection target elements, it becomes possible to accurately adjust the connection state of the adjustment circuit and more reliably achieve the desired operation of the circuit.

In one embodiment, the plurality of disconnection target elements may each be formed of a fuse. The plurality of fuses may be disposed side by side in the width direction of the fuses. The disconnection step may include disconnecting at least one of the disconnection target elements among the plurality of fuses along the width direction of the fuses.

In one embodiment, the adjustment circuit may be configured such that the first node is at a first voltage when none of the plurality of disconnection target elements are disconnected, and the first node is at a second voltage when at least one of the plurality of disconnection target elements is disconnected.

An adjustment method according to one embodiment is a method that uses an adjustment circuit disposed between a first node and a second node. The adjustment circuit comprises a signal generation circuit and a plurality of disconnection target elements and is configured such that the signal generation circuit outputs a first voltage to the first node when none of the plurality of disconnection target elements are disconnected, and the signal generation circuit outputs a second voltage to the first node when at least one of the plurality of disconnection target elements is disconnected. The adjustment method includes a disconnection step that disconnects at least one of the plurality of disconnection target elements.

According to this configuration, even if the disconnection of some of the disconnection target elements among the plurality of disconnection target elements fails, as long as at least one disconnection target element is disconnected, the voltage output by the adjustment circuit can be adjusted to the desired voltage. Therefore, by disconnecting the disconnection target elements, it becomes possible to accurately adjust the signal generated and more reliably achieve the desired operation of the circuit.

A current adjustment method according to one embodiment is a method for adjusting an amount of current flowing in an active load circuit, in which the current is generated by a current generation circuit, using a current adjustment circuit. The current adjustment circuit may comprise a sink circuit which comprises a switching element and adjusts the amount of current by sinking a current depending on whether the switching element is on or off from the current generation circuit, and a control circuit comprising the adjustment circuit. A voltage corresponding to a voltage at the first node may be input to an input terminal of the switching element. A predetermined voltage may be supplied to the second node. On/off of the switching element may be controlled depending on whether the voltage at the first node is the first voltage or the second voltage. The current adjustment method may include the disconnection step.

An offset adjustment method according to one embodiment is a method for adjusting an input offset voltage of an operational amplifier. The operational amplifier may include a current generation circuit and the current adjustment circuit. The current generation circuit may be an input differential pair comprising a first MOS transistor to which a first input voltage is input and a second MOS transistor to which a second input voltage is input. The sink circuit may be configured to adjust an amount of one of a first drain current and a second drain current flowing in the active load circuit by sinking one of the first drain current flowing in the first MOS transistor and the second drain current flowing in the second MOS transistor. The offset adjustment method may include the disconnection step.

In one embodiment, the sink circuit may comprise two switching elements, one of which is a first switching element connected to a drain of the first MOS transistor and the other of which is a second switching element connected to a drain of the second MOS transistor. The control circuit may comprise a plurality of adjustment circuits including a first adjustment circuit and a second adjustment circuit. A voltage corresponding to a voltage at a first node of the first adjustment circuit may be input to an input terminal of the first switching element. A voltage corresponding to a voltage at a first node of the second adjustment circuit may be input to an input terminal of the second switching element. The sink circuit may be configured to sink one of the first drain current and the second drain current via a switching element that is turned on among the first switching element or the second switching element. The disconnection step may include disconnecting a disconnection target element that is comprised in one of the first adjustment circuit and the second adjustment circuit.

### Embodiments

Hereinafter, preferred embodiments are described with reference to the figures. Identical or equivalent elements, components, and processes shown in each figures are denoted by the same reference numerals, and redundant explanations are omitted as appropriate. Furthermore, the embodiments are not intended to limit the disclosure and invention, but are merely examples, and all features and combinations thereof described in the embodiments may not necessarily be essential to the essence of the disclosure and invention.

In this specification, “a state in which component A is connected to component B” includes not only cases in which component A and component B are physically directly connected to each other, but also cases in which component A and component B are indirectly connected to each other through other components that do not substantially affect their electrical connection state between them or do not impair the functions or effects achieved by the connection between them.

Similarly, “a state in which component C is connected (disposed) between component A and component B” includes not only cases in which component A and component C, or component B and component C are directly connected, but also cases where they are indirectly connected via other components that do not substantially affect their electrical connection state between them or do not impair the functions or effects achieved by the connection between them.

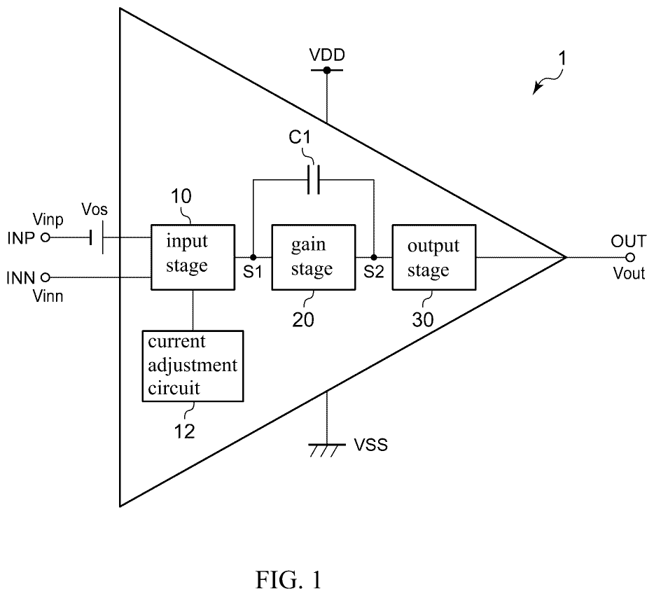

FIG. 1 is a schematic block diagram of an operational amplifier 1 according to one embodiment of the present disclosure. As shown in FIG. 1, the operational amplifier 1 according to this embodiment primarily includes an input stage 10, a current adjustment circuit 12, a gain stage 20, an output stage 30, a capacitor C1, a first input terminal INP (non-inverting input terminal), a second input terminal INN (inverting input terminal), and an output terminal OUT.

The operational amplifier 1 is supplied with a positive power supply voltage VDD and a negative power supply voltage VSS (for example, 0V). A first input voltage Vinp is input to the first input terminal INP, and a second input voltage Vinn is input to the second input terminal INN. The operational amplifier 1 according to this embodiment has an input offset voltage Vos. The operational amplifier 1 amplifies the voltage obtained by adding the input offset voltage Vos to the difference between the first input voltage Vinp and the second input voltage Vinn, thereby generating an output voltage Vout.

The input stage 10 generates a first signal S1 corresponding to the difference between the first input voltage Vinp and the second input voltage Vinn, as well as the input offset voltage Vos. Specifically, the input stage 10 comprises an input differential pair (current generating circuit) described later, which generates a differential current. The first signal S1 corresponding to this differential current is input to the gain stage 20.

The current adjustment circuit 12 is configured to adjust the amount of current flowing from the input differential pair comprised in the input stage 10 to the gain stage 20. Specifically, the current adjustment circuit 12 adjusts the amount of current flowing to the gain stage 20 by sinking a portion of the differential current. As a result, the input offset voltage Vos of the operational amplifier 1 can be adjusted.

The gain stage 20 functions as an active load circuit for the input stage 10. Specifically, the gain stage 20 amplifies the first signal S1 and generates a second signal S2. A capacitor C1 for phase compensation is provided in the gain stage 20. The output stage 30 generates an output signal Vout corresponding to the second signal S2.

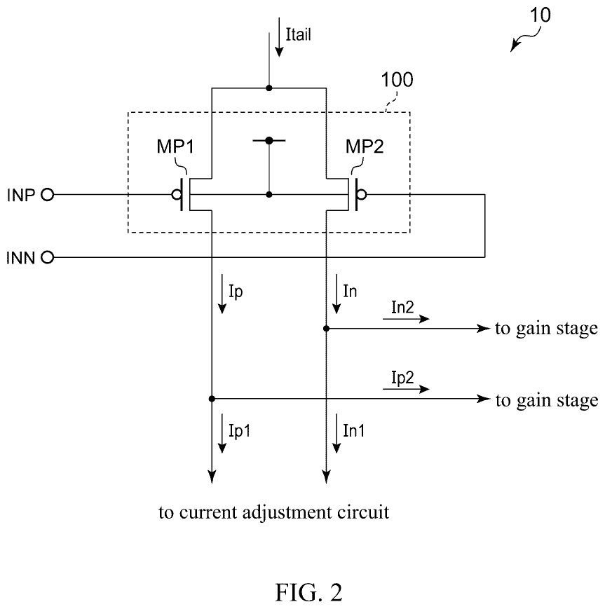

FIG. 2 is a circuit diagram of the input stage 10 according to this embodiment. The input stage 10 according to this embodiment comprises an input differential pair 100 formed of a transistor MP1 (first MOS transistor) where the first input voltage Vinp is input and a transistor MP2 (second MOS transistor) where the second input voltage Vinn is input. The transistors MP1 and MP2 according to this embodiment are each formed of P-channel MOS (Metal Oxide Semiconductor) transistors. Furthermore, in this embodiment, an example is described where the input differential pair 100 is formed of two P-channel MOS transistors, but the input differential pair 100 may also be formed of two N-channel MOS transistors.

The input stage 10 is configured such that the tail current Itail supplied from a current source (not shown) is provided to the sources of the input differential pair 100 (specifically, the sources of transistors MP1 and MP2). The base of transistor MP1 is connected to the first input terminal INP, and the drain of transistor MP1 is connected to the current adjustment circuit 12 and the gain stage 20. The base of transistor MP2 is connected to the second input terminal INN, and the drain of transistor MP2 is connected to the current adjustment circuit 12 and the gain stage 20.

In this embodiment, a portion of the drain current Ip of transistor MP1 or a portion of the drain current In of transistor MN2 is sunk into the current adjustment circuit 12. For example, when a portion of the drain current Ip of transistor MP1, denoted as current Ip1, is sunk into the current adjustment circuit 12, the remaining drain current Ip2 (Ip−Ip1) flows to the gain stage 20. Additionally, when a portion of the drain current In of transistor MP2, denoted as current In1, is sunk into the current adjustment circuit 12, the remaining drain current In2 (=In−In1) flows to the gain stage 20. As such, the drain currents Ip2 and In2 flowing from the input differential pair 100 to the gain stage 20 are adjusted.

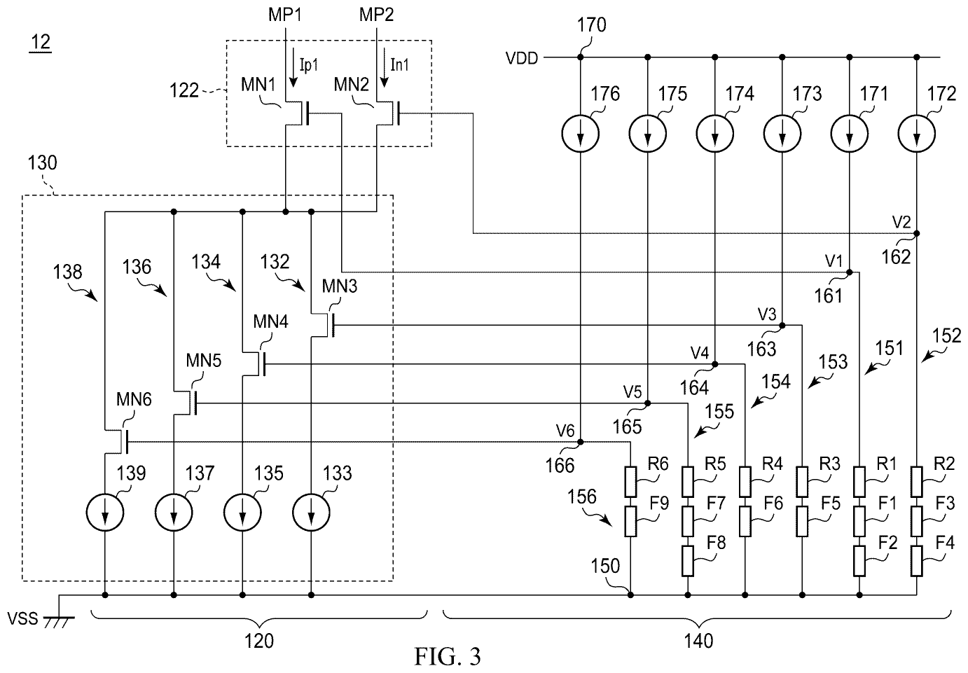

FIG. 3 is a circuit diagram of the current adjustment circuit 12 according to this embodiment. The current adjustment circuit 12 adjusts the amount of current from the current (drain current) generated by the input differential pair 100 flowing to the gain stage 20. The current adjustment circuit 12 according to this embodiment comprises a sink circuit 120 and a control circuit 140.

The sink circuit 120 comprises a switching element and adjusts the amount of current flowing to the gain stage 20 by sinking current from the input differential pair 100 depending on whether the switching element is on or off. More specifically, the sink circuit 120 adjusts the amount of one of a first drain current Ip and a second drain current In flowing in the gain stage 20 by sinking one of the first drain current Ip flowing through the first transistor P1 and the second drain current In flowing through the second transistor P2. The sink circuit 120 according to this embodiment comprises a switch section 122 and a group of current paths 130. The group of current paths 130 is provided between the switch section 122 and a ground node 150 where a ground (reference voltage VSS) is supplied.

The switch section 122 is configured to determine the drain current sunk into the sink circuit 120 from the drain current Ip and the drain current In in response to control by the control circuit 140. The switch section 122 comprises a transistor MN1 (first switching element) and a transistor MN2 (second switching element). The transistor MN1 and the transistor MN2 are each formed of N-channel MOS transistors. The drain of transistor MN1 is connected to the drain of transistor MP1, and the drain of transistor MN2 is connected to the drain of transistor MP2.

The sink circuit 120 sinks one of the drain currents, either the first drain current Ip or the second drain current In, via a transistor that is turned on among transistor MN1 or transistor MN2. For example, when the transistor MN1 is on and the transistor MN2 is off, a portion of the first drain current Ip, denoted as current Ip1, is sunk into the sink circuit 120 (In1=0). On the other hand, when the transistor MN1 is off and the transistor MN2 is on, a portion of the second drain current In, denoted as current In1, is sunk into the sink circuit 120 (Ip1=0).

The group of current paths 130 is configured to allow the currents Ip1 and In1 to flow into the sink circuit 120. The group of current paths 130 according to this embodiment comprises a plurality of current paths with different current-sinking capabilities, particularly comprising a first current path 132, a second current path 134, a third current path 136, and a fourth current path 138. Furthermore, in this embodiment, an example with four current paths in the group of current paths 130 is illustrated, but the number of current paths is not limited to four; it may be three or fewer, or five or more.

The first current path 132 comprises a transistor MN3 formed of an N-channel MOS transistor and a current source 133. The drain of transistor MN3 is connected to the source of the switch section 122. The current source 133 is disposed between the source of transistor MN3 and the ground node 150.

The second current path 134 comprises a transistor MN4 formed of an N-channel MOS transistor and a current source 135. The drain of transistor MN4 is connected to the source of the switch section 122. The current source 135 is disposed between the source of transistor MN4 and the ground node 150.

The third current path 136 comprises a transistor MN5 formed of an N-channel MOS transistor and a current source 137. The drain of transistor MN5 is connected to the source of the switch section 122. The current source 137 is disposed between the source of transistor MN5 and the ground node 150.

The fourth current path 138 comprises a transistor MN6 formed of an N-channel MOS transistor and a current source 139. The drain of transistor MN6 is connected to the source of the switch section 122. The current source 139 is disposed between the source of transistor MN6 and the ground node 150.

The operation (on, off) of transistors MN1 to MN6 is controlled by a control circuit 140, as will be described later.

The sink circuit 120 sinks one of the drain currents, either the first drain current Ip or the second drain current In, via a current path where the transistors MN3 to MN6 that are turned on are provided, among the plurality of current paths (the first current path 132, the second current path 134, the third current path 136, and the fourth current path 138).

The first current path 132, the second current path 134, the third current path 136, and the fourth current path 138 have different current-sinking capacities. Specifically, the current-sinking capacities of current sources 133, 135, 137, and 139 are a magnitude obtained by multiplying a reference capacity S by a power of two. Specifically, the current-sinking capacity of the current source 133 is S, the current-sinking capacity of the current source 135 is 2S, the current-sinking capacity of the current source 137 is 4S, and the current-sinking capacity of the current source 139 is 8S.

The transistors MN3 to MN6 may have priorities defined based on the current-sinking capabilities of corresponding current paths and standard deviations a of the input offset voltages Vos of the operational amplifier 1. As will be described in detail later, in this embodiment, the transistor MN5 has the highest priority.

The control circuit 140 comprises the first to sixth connection paths 151 to 156 (adjustment circuits) and current sources 171 to 176. The first to sixth connection paths 151 to 156 are each disposed between the first node and the second node.

In this embodiment, the first connection path 151, the second connection path 152, and the fifth connection path 155 each comprise a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected. Furthermore, these connection paths are provided such that the voltage at the first node is a first voltage when none of the disconnection target elements are disconnected, and the voltage at the first node becomes a second voltage when at least one of the disconnection target elements is disconnected.

The first connection path 151 is disposed between a node 161 (first node), which is connected to the gate of transistor MN1, and the ground node 150 (second node). The first connection path 151 is formed by connecting a first resistor R1, a first fuse F1, and a second fuse F2 in series in this order from the node 161 side. The end of the first resistor R1 opposite to the first fuse F1 is connected to the gate of transistor MN1. The end of the second fuse F2 opposite to the first fuse F1 is connected to the ground node 150.

The second connection path 152 is disposed between a node 162 (first node), which is connected to the gate of transistor MN2, and the ground node 150 (second node). The second connection path 152 is formed by connecting a second resistor R2, a third fuse F3, and a fourth fuse F4 in series in this order from the node 162 side. The end of the second resistor R2 opposite to the third fuse F3 is connected to the gate of transistor MN2. The end of the fourth fuse F4 opposite to the third fuse F3 is connected to the ground node 150.

The third connection path 153 is disposed between a node 163 (first node), which is connected to the gate of transistor MN3, and the ground node 150 (second node). The third connection path 153 is formed by connecting a third resistor R3 and a fifth fuse F5 in series in this order from the node 163 side. The end of the third resistor R3 opposite to the fifth fuse F5 is connected to the gate of transistor MN3. The end of the fifth fuse F5 opposite to the third resistor R3 is connected to the ground node 150.

The fourth connection path 154 is disposed between a node 164 (first node), which is connected to the gate of transistor MN4, and the ground node 150 (second node). The fourth connection path 154 is formed by connecting a fourth resistor R4 and a sixth fuse F6 in series in this order from the node 164 side. The end of the fourth resistor R4 opposite to the sixth fuse F6 is connected to the gate of transistor MN4. The end of the sixth fuse F6 opposite to the fourth resistor R4 is connected to the ground node 150.

The fifth connection path 155 is disposed between a node 165 (first node), which is connected to the gate of transistor MN5, and the ground node 150 (second node). The fifth connection path 155 is formed by connecting a fifth resistor R5, a seventh fuse F7, and an eighth fuse F8 in series in this order from the node 165 side. The end of the fifth resistor R5 opposite to the seventh fuse F7 is connected to the gate of transistor MN5. The end of the eighth fuse F8 opposite to the seventh fuse F7 is connected to the ground node 150.

The sixth connection path 156 is disposed between a node 166 (first node), which is connected to the gate of transistor MN6, and the ground node 150 (second node). The sixth connection path 156 is formed by connecting a sixth resistor R6 and a ninth fuse F9 in series in this order from the node 166 side. The end of the sixth resistor R6 opposite to the ninth fuse F9 is connected to the gate of transistor MN6. The end of the ninth fuse F9 opposite to the sixth resistor R6 is connected to the ground node 150. Furthermore, the first to sixth resistors R1 to R6 are resistors for gate protection.

When none of the first to ninth fuses F1 to F9 are disconnected, the nodes 161 to 166 are each electrically connected to the ground node 150 through their corresponding connection paths among the first connection path 151 to the sixth connection path 156.

The first to ninth fuses F1 to F9 may be disconnected, for example, by a laser. When any of the first to ninth fuses F1 to F9 are disconnected, the connection path comprising the disconnected fuse will be interrupted. When a connection path comprising a plurality of fuses (the first connection path 151, the second connection path 152, and the fifth connection path 155) has at least one fuse disconnected among the plurality of fuses, the connection path will become open as viewed from the first node.

For example, when at least one of the first fuse F1 and the second fuse F2 is disconnected, the first connection path 151 becomes open as viewed from the node 161. Furthermore, when at least one of the third fuse F3 and the fourth fuse F4 is disconnected, the second connection path 152 becomes open as viewed from the node 162. Additionally, when the fifth fuse F5 is disconnected, the third connection path 153 becomes open as viewed from the node 163. Furthermore, when the sixth fuse F6 is disconnected, the fourth connection path 154 becomes open as viewed from the node 164. Furthermore, when at least one of the seventh fuse F7 and the eighth fuse F8 is disconnected, the fifth connection path 155 becomes open as viewed from the node 165. Furthermore, when the ninth fuse F9 is disconnected, the sixth connection path 164 becomes open as viewed from the node 166.

The current sources 171 to 176 are each disposed between a power voltage node 170, where the power supply voltage VDD is supplied, and the first node of the corresponding connection path among the first connection path 151 to the sixth connection path 156.

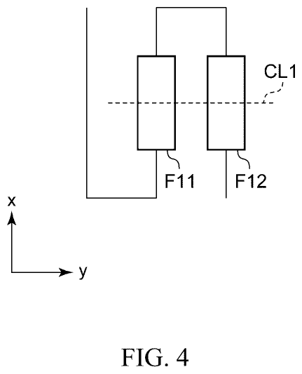

FIG. 4 shows an example layout of two fuses F11 and F12 that are connected in series in a connection path. The fuses F11 and F12 shown in FIG. 4 can be the first fuse F1 and the second fuse F2 of the first connection path 151, the third fuse F3 and the fourth fuse F4 of the second connection path 152, or the seventh fuse F7 and the eighth fuse F8 of the fifth connection path 155.

In FIG. 4, the length direction of the fuses F11 and F12 is indicated by the x-axis, and the width direction of the fuses F11 and F12 is indicated by the y-axis, with the x-axis and y-axis being orthogonal to each other. As shown in FIG. 4, the fuses F11 and F12 are disposed side by side in the width direction (y-axis direction). This allows for the simultaneous disconnection of the fuses F11 and F12 along a cut line CL1 indicated by the dashed line in FIG. 4, for example. Therefore, it is not necessary to disconnect the fuses F11 and F12 individually, and the disconnection of the fuses F11 and F12 becomes more efficient. Furthermore, an example where the fuses F11 and F12 are disposed in parallel is shown in FIG. 4, but the fuses F11 and F12 may be disposed diagonally.

Herein, the offset adjustment method (including current adjustment method) for adjusting the input offset voltage Vos of the operational amplifier 1 will be described. The offset adjustment method (including current adjustment method) according to this embodiment includes a disconnection step that disconnects at least one of the fuses among the plurality of fuses comprised in the adjustment circuit (the first connection path 151, the second connection path 152, and the fifth connection path 155).

For example, the disconnection step may include disconnecting a fuse comprised in one of the connection circuits of the first connection path 151 and the second connection path 152. Accordingly, one of the transistors MN1 and MN2 is turned on and the other is turned off. As a result, one of the first drain current Ip and the second drain current In is sunk into the sink circuit 120.

Additionally, the disconnection step may include disconnecting a fuse comprised in the third to sixth connection paths 153 to 156 corresponding to the transistors MN3 to MN6. For example, at least one of the two fuses (the seventh fuse F7 and the eighth fuse F8) comprised in the fifth connection path 155 may be disconnected. Accordingly, the transistor MN5 turns on, allowing current to flow through the third current path 136. Similarly, for other current paths, current can flow by disconnecting a fuse in a corresponding connection path.

By the current being sunk into the sink circuit 120, the amount of current flowing from the input differential pair 100 to the gain stage 20 is adjusted, affecting the subsequent stages (including the gain stage 20 and the output stage 30) beyond the input stage 10. As a result, the input offset voltage Vos of the operational amplifier 1 is adjusted. In detail, the input offset voltage Vos appears to be adjusted for the entire circuit of the operational amplifier 1.

Additionally, when a plurality of fuses are disposed side by side in the width direction, the disconnection step may disconnect a plurality of disconnection target elements along the width direction of the plurality of fuses. This allows for reliable and simple disconnection of at least one of the plurality of fuses.

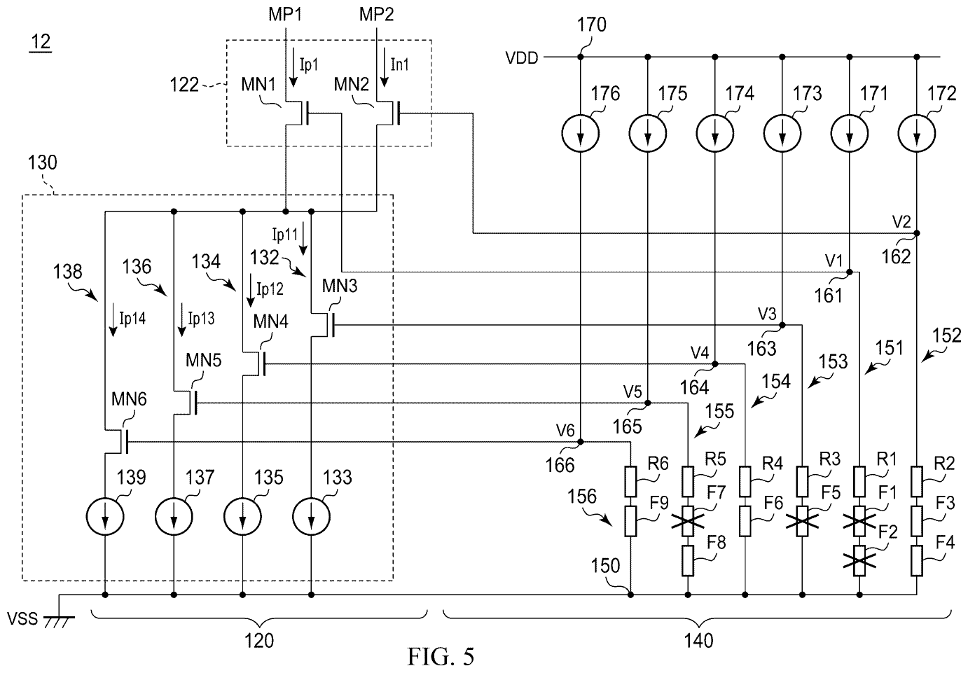

An example of the operation of the current adjustment circuit 12 according to this embodiment will be described below. FIG. 5 is a circuit diagram illustrating an example of the operation of the current adjustment circuit 12 after the fuses are disconnected. In the example shown in FIG. 5, the first fuse F1, the second fuse F2, the fifth fuse F5, and the seventh fuse F7 are disconnected.

A voltage corresponding to the first node of the corresponding connection path is input to the gates of the transistors MN1 to MN6, and the operation is controlled according to the voltage. Specifically, on/off of the transistors MN1 to MN6 is controlled depending on whether the voltage of the first node of the corresponding connection path is the first voltage or the second voltage. Accordingly, the current sunk by the sink circuit 120 is adjusted.

The first connection path 151 as viewed from the gate of transistor MN1, the third connection path 153 as viewed from the gate of transistor MN3, and the fifth connection path 155 as viewed from the gate of transistor MN5 are each open. Additionally, the gate of transistor MN2 is electrically connected to the ground node 150 via the second connection path 152, the gate of transistor MN4 is electrically connected to the ground node 150 via the fourth connection path 154, and the gate of transistor MN6 is electrically connected to the ground node 150 via the sixth connection path 156.

Since the first connection path 151 is open, the voltage V1 at the node 161 becomes a high voltage (the second voltage) corresponding to the power supply voltage VDD. Therefore, a high voltage is input to the gate of transistor MN1, turning it on. As a result, the current Ip1, which is a portion of the drain current Ip from the transistor MP1, is sunk in the sink circuit 120 via the transistor MN1.

The resistance of the second connection path 152 is sufficiently small. Therefore, the power supply voltage VDD drops almost entirely across the current source 172, and the voltage V2 at the node 162 becomes substantially equal to the reference voltage VSS, which is a low voltage (the first voltage). Accordingly, a low voltage is input to the gate of transistor MN2, turning off the transistor MN2. As a result, the drain current In from the transistor MP2 does not flow through the transistor MN2 (In1=0).

The voltages V3 and V5 at the nodes 163 and 165 are both high, similar to the node 161. Accordingly, each of the transistors MN3 and MN5 is turned on. The voltages V4 and V6 at the nodes 164 and 166 are low, similar to the node 162. Accordingly, each of the transistors MN4 and MN6 is turned off.

Due to the transistors MN3 and MN5 being turned on, a current Ip11 flows through the first current path 132, and a current Ip13 flows through the third current path 136. On the other hand, since the transistors MN4 and MN6 are turned off, no current flows through the second current path 134 and the fourth current path 138 (Ip12=0, Ip14=0).

As described above, in the example shown in FIG. 5, the sink circuit 120 sinks the current Ip1 (which equals Ip11+Ip13) from the transistor MP1. In response to this sunk current Ip1, the input offset voltage Vos of the operational amplifier 1 is adjusted to be smaller.

Herein, the transistors MN1 and MN2 are switching elements for determining which of the drain currents of the transistors MP1 and MP2 in the input differential pair 100 will be sunk, and thus their operation is important. Herein, in this embodiment, the first connection path 151 and the second connection path 152 each have two fuses disposed in series. Therefore, even if the disconnection of one of the fuses fails, it is sufficient to be able to disconnect the other fuse, allowing for a more reliable opening of the connection path that should be opened. As a result, it becomes possible to control the operation of transistors MN1 and MN2 more accurately.

As such, by adjusting the number of fuses in the corresponding connection paths according to the importance of transistors MN1 to MN6, it becomes possible to achieve more reliable and appropriate current adjustments.

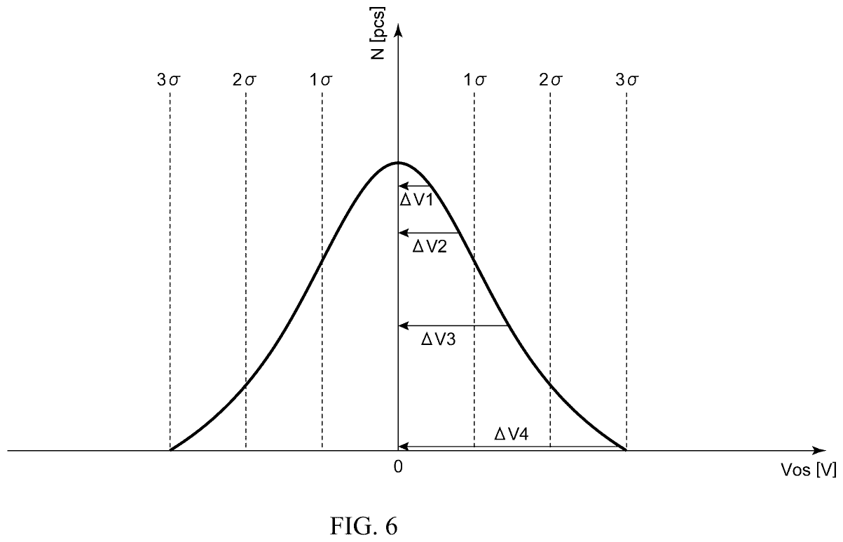

FIG. 6 is a diagram illustrating the amount by which the input offset voltage Vos can be adjusted by each of the first current path 132, the second current path 134, the third current path 136, and the fourth current path 138 sinking current (hereinafter referred to as “adjustment voltage”). FIG. 6 shows a distribution of the input offset voltage Vos of operational amplifier 1. The distribution of the input offset voltage Vos shown in FIG. 6 follows a normal distribution with an average of 0V.

ΔV1 to ΔV4 shown in FIG. 6 are adjustment voltages resulting from one of the current paths of the first current path 132, the second current path 134, the third current path 136, and the fourth current path 138 sinking current. Specifically, ΔV1 is the adjustment voltage resulting from the first current path 132 sinking current Ip11, ΔV2 is the adjustment voltage resulting from the second current path 134 sinking current Ip12, ΔV3 is the adjustment voltage resulting from the third current path 136 sinking current Ip13, and ΔV4 is the adjustment voltage resulting from the fourth current path 138 sinking current Ip14.

The larger the amount of current sunk, the larger the adjustment voltage. Therefore, in this embodiment, since 0<Ip11<Ip12<Ip13<Ip14, 0<ΔV1<ΔV2<ΔV3<ΔV4. Herein, if the standard deviation of the input offset voltage Vos is σ, then ΔV1<ΔV2<σ<ΔV3<2σ<3σ=ΔV4 is satisfied.

Herein, when it is desired to keep the input offset voltage Vos within ±σ, in most cases, the adjustment voltage ΔV3 can bring the input offset voltage Vos within ±σ. Consequently, by opening the fifth connection path 155 and allowing current Ip13 to flow through the third current path 136, it is often possible to keep the input offset voltage Vos within ±σ. Therefore, the chances of disconnecting the fuse of the fifth connection path 155 are increased.

Herein, in this embodiment, among the transistors MN3 to MN6, the transistor MN5 has the highest priority, and the fifth connection path 155 corresponding to transistor MN5 is provided with two fuses (the seventh fuse F7 and the eighth fuse F8) disposed in series. Therefore, even if the disconnection of one fuse fails when disconnecting the fuses, it is sufficient to disconnect the other fuse, allowing for a more reliable opening of the fifth connection path 155. As a result, it becomes possible to more accurately keep the input offset voltage Vos within the target value.

A laser disconnecting device is used for disconnecting fuses. However, due to issues such as insufficient precision of the disconnecting device, there may be instances where the fuse cannot be disconnected. The reason why the fuse cannot be disconnected is presumably due to insufficient laser output and a disconnecting error caused by a misalignment in the position where the laser is irradiated. Accordingly, the yield of devices (for example, operational amplifiers) that include the fuses that should be disconnected may be reduced.

The operational amplifier 1 according to this embodiment comprises a first connection path 151 (adjustment circuit) disposed between the node 161 (first node) and the ground node 150 (second node). The first connection path 151 comprises a first fuse F1 and a second fuse F2 (a plurality of disconnection target elements) connected in series. When neither the first fuse F1 nor the second fuse F2 is disconnected, the node 161 and the ground node 150 are electrically connected via the first connection path 151. When at least one of the first fuse F1 and the second fuse F2 (disconnection target elements) is disconnected, the first connection path 151 is configured to be open as viewed from the node 161.

According to this configuration, even if the disconnection of either the first fuse F1 or the second fuse F2 fails, as long as the other fuse can be disconnected, the first connection path 151 can be opened as viewed from the node 161. Therefore, it becomes possible to accurately adjust the connection state of the first connection circuit 151 through the disconnection of the target elements and more reliably achieve the desired operation of the circuit. The second connection path 152 and the fifth connection path 155 configured similarly to the first connection circuit 151 can also achieve a similar effect.

Additionally, the operational amplifier 1 according to this embodiment includes a current adjustment circuit 12 that comprises a sink circuit 120 and a control circuit 140. The sink circuit 120 comprises transistors MN1 to MN6 (switching elements) and adjusts the amount of current flowing from the input differential pair 100 (current generation circuit) to the gain stage 20 (active load circuit) by sinking current depending on whether the switching elements are on or off from the input differential pair 100. The control circuit 140 comprises the first connection path 151 (adjustment circuit).

A voltage corresponding to the voltage at the node 161 is input to the gate of the transistor MN1 (input terminal of the switching element). A reference voltage VSS (a predetermined voltage) is supplied to the node 150. On/off of the transistor MN1 is controlled depending on whether the voltage at node 150 is at a low voltage (first voltage) or a high voltage (second voltage). Herein, the first connection circuit 151 is provided so that when neither the first fuse F1 nor the second fuse F2 connected in series is disconnected, the node 161 becomes a low voltage (first voltage), and when at least one of the first fuse F1 and the second fuse F2 is disconnected, the node 161 becomes a high voltage (second voltage).

According to this configuration, since the first connection path 151 can be opened more reliably as described above, the voltage at the node 161 can be controlled more accurately. As a result, the amount of current sunk by the current adjustment circuit can be adjusted more accurately.

Furthermore, the operational amplifier 1 according to this embodiment includes an input differential pair 100 (current generation circuit) and the current adjustment circuit 12. The input differential pair 100 comprises a transistor MP1 (first MOS transistor) to which a first input voltage Vinp is input and a transistor MP2 (second MOS transistor) to which a second input voltage Vinn is input. The sink circuit 120 adjusts the amount of one of the first drain current and the second drain current flowing to the gain stage 20 (active load circuit) by sinking one of the first drain current flowing to the transistor MP1 and the second drain current flowing to the transistor MP2.

According to this configuration, as the drain current is sunk by the sink circuit 120, the amount of current flowing through the gain stage 20 is adjusted, and the stages subsequent to the input stage 10 (including the gain stage 20 and the output stage 30) are affected. This allows for the adjustment of the input offset voltage Vos of the operational amplifier 1.

### (First Modification)

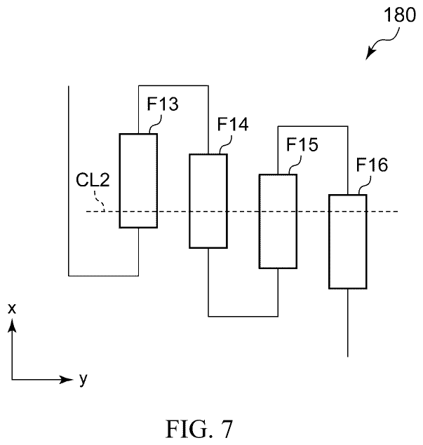

FIG. 7 is a diagram showing a layout of fuses F13 to F16 provided in a connection path 180 according to the first modification. In FIG. 7, the x-axis and y-axis are axes orthogonal to each other. The connection path 180 according to the first modification includes the fuses F13 to F16 connected in series. These fuses F13 to F16 are disposed side by side in the width direction (x-axis direction). However, these fuses F13 to F16 are offset in the length direction (y-axis direction). Even if the fuses F13 to F16 are offset in the length direction, as long as the amount of offset falls within an appropriate range, the fuses F13 to F16 can be disconnected along a cut line CL2 of the width direction indicated by the dashed line.

### (Second Modification)

In the above embodiment, an example in which the connection path forming the adjustment circuit comprises two fuses connected in series has been described. However, the adjustment circuit may comprise three or more fuses connected in series.

### (Third Modification)

In the above embodiment, an example using N-channel MOS transistors (transistors MN1 to MN6) as switching elements has been described. However, the switching elements may also be analog switches that combine P-channel MOS transistors and N-channel MOS transistors, or may be P-channel MOS transistors.

### (Fourth Modification)

The adjustment circuit may comprise different numbers of fuses connected in series depending on the priorities of the switching elements. For example, assume that the transistors MN1 and MN2 have the highest priority, followed by a switching element provided in one of the plurality of current paths. In this case, if the number of fuses in two adjustment circuits corresponding to the transistor MN1 and the transistor MN2 is N1, the number of fuses in the adjustment circuit corresponding to the switching element with the next highest priority is N2, and the number of fuses in the adjustment circuit corresponding to the remaining switching element is N3, then N3<N2<N1 may be satisfied.

### (Fifth Modification)

In the above embodiment, an example in which the first node of the connection path is directly connected to the gate of the corresponding transistor has been described. Without being limited to this, the first node of the connection path may be connected to the gate of the corresponding transistor via any circuit (for example, an OR circuit, etc.).

### Second Embodiment

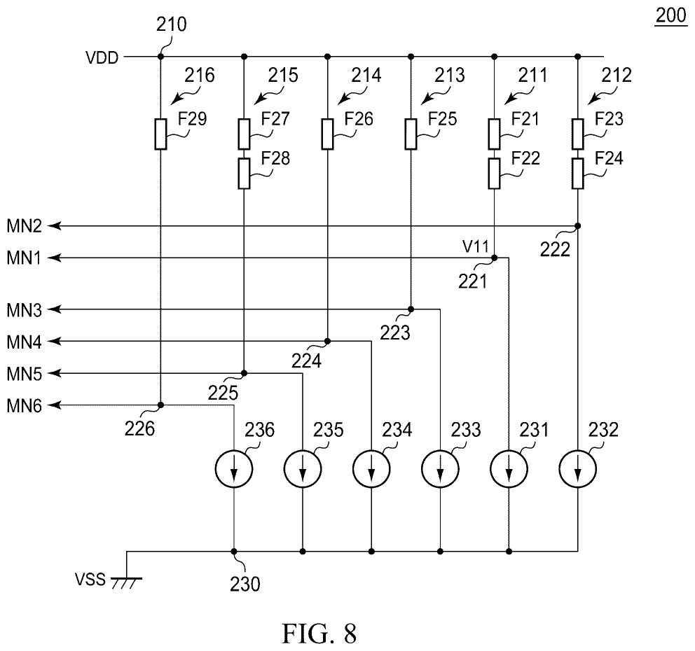

FIG. 8 is a circuit diagram of the control circuit 200 according to the second embodiment. Instead of the control circuit 140 according to the first embodiment, the control circuit 200 according to the second embodiment may be provided in the current adjustment circuit 12. The control circuit 200 according to the second embodiment differs from the control circuit 140 according to the first embodiment in that the switching element corresponding to the connection path in which the disconnection target element is disconnected is turned off. The control circuit 200 according to the second embodiment comprises first to sixth connection paths 211 to 216 (adjustment circuits) and current sources 231 to 236.

The first connection path 211 is disposed between a node 221 (first node), which is connected to the gate of transistor MN1, and a power supply voltage node 210 (second node). The first connection path 211 is formed by connecting fuses F22 and F21 in series in this order from the node 221 side.

The second connection path 212 is disposed between a node 222 (first node), which is connected to the gate of transistor MN2, and a power supply voltage node 210 (second node). The second connection path 212 is formed by connecting fuses F24 and F23 in series in this order from the node 222 side.

The third connection path 213 is disposed between a node 223 (first node), which is connected to the gate of transistor MN3, and a power supply voltage node 210 (second node). The third connection path 213 is formed of a fuse F25.

The fourth connection path 214 is disposed between a node 224 (first node), which is connected to the gate of transistor MN4, and a power supply voltage node 210 (second node). The fourth connection path 214 is formed of a fuse F26.

The fifth connection path 215 is disposed between a node 225 (first node), which is connected to the gate of transistor MN5, and a power supply voltage node 210 (second node). The fifth connection path 215 is formed by connecting fuses F28 and F27 in series in this order from the node 225 side.

The sixth connection path 216 is disposed between a node 226 (first node), which is connected to the gate of transistor MN6, and the power supply voltage node 210 (second node). The sixth connection path 216 is formed of a fuse F29.

When none of the fuses F21 to F29 are disconnected, the nodes 221 to 226 are each electrically connected to the power supply voltage node 210 via their corresponding connection paths among the first connection path 211 to the sixth connection path 216.

When any of the fuses F21 to F29 are disconnected, the connection path comprising the disconnected fuse will be open as viewed from the corresponding first node. Connection paths (the first connection path 211, the second connection path 212, and the fifth connection path 215) comprising a plurality of fuses will be open as viewed from the corresponding first node when at least one of the fuses among the plurality of fuses is disconnected.

The current sources 231 to 236 are each disposed between the ground node 230 and the first node of the corresponding connection path among the first connection path 211 to the sixth connection path 216.

In the control circuit 200 according to the second embodiment, a transistor corresponding to a connection path comprising a disconnected fuse is turned off, and a transistor corresponding to a connection path not comprising a disconnected fuse is turned on.

For example, assume that neither the fuse F21 nor the fuse F22 of the first connection path 211 is disconnected. In this case, the voltage V11 of the node 221 is substantially the high voltage (first voltage) of the power supply voltage VDD. As a result, the transistor MN1 connected to the node 221 is turned on.

On the other hand, assume that at least one of the fuses F21 and F22 of the first connection path 211 is disconnected. In this case, the voltage V11 of the node 221 becomes substantially the low voltage (second voltage) of the reference voltage VSS. As a result, the transistor MN1 connected to the node 221 is turned off.

Other transistors MN2 to MN6 are also controlled similarly to the transistor MN1 depending on the disconnection state of the fuses.

In the operational amplifier using the control circuit 200 according to this embodiment, similar effects to those of the operational amplifier 1 according to the first embodiment can also be achieved.

### Third Embodiment

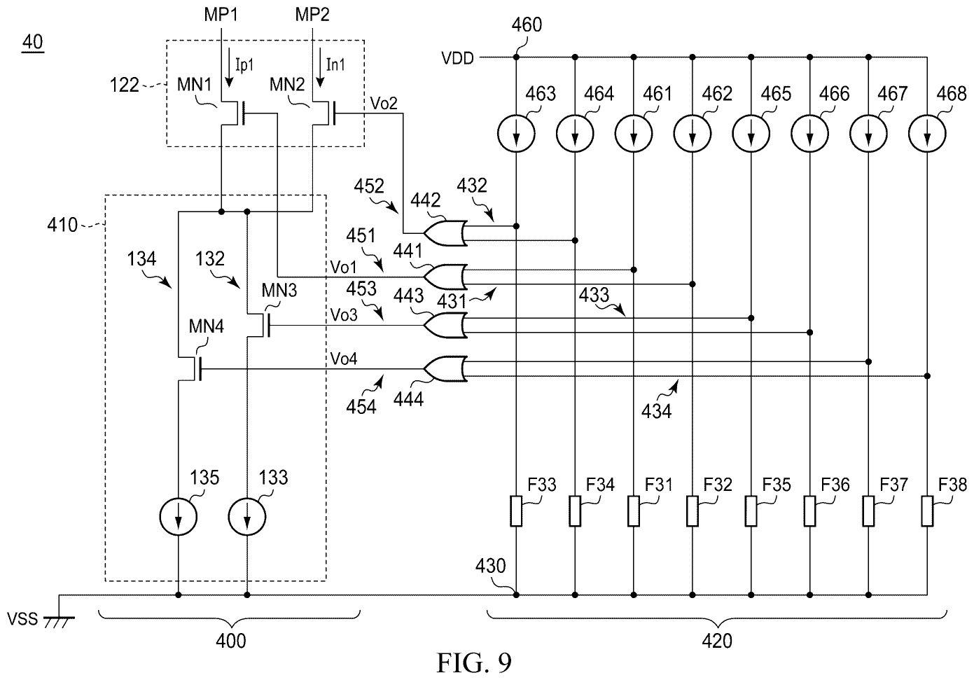

FIG. 9 is a circuit diagram of the current adjustment circuit 40 according to the third embodiment. In FIG. 9, components having substantially the same function as those in the current adjustment circuit 12 according to the first embodiment are denoted by the same reference numerals, and their descriptions are omitted as appropriate. The current adjustment circuit 40 according to the third embodiment mainly differs from the adjustment circuits according to the first embodiment or the second embodiment in the configuration of the adjustment circuit comprised in the control circuit 420. The current adjustment circuit 40 according to the third embodiment comprises a sink circuit 400 and a control circuit 420.

The sink circuit 400 according to this embodiment comprises a switch section 122 and a group of current paths 410. The group of current paths 410 is provided between the switch section 122 and a ground node 430. The group of current paths 410 according to this embodiment comprises a first current path 132 and a second current path 134.

The control circuit 420 according to this embodiment comprises a first adjustment circuit 431, a second adjustment circuit 432, a third adjustment circuit 433, a fourth adjustment circuit 434, and current sources 461 to 468.

The first adjustment circuit 431 is disposed between a node 451 (first node), which is connected to the gate of transistor MN1, and the ground node 430 (second node). The first adjustment circuit 431 comprises an OR circuit 441 (signal generation circuit) and a plurality of fuses F31 and F32 (disconnection target element). The OR circuit 441 outputs a voltage Vo1 depending on the disconnection state of the fuses F31 and F32. The first adjustment circuit 431 is provided such that the OR circuit 441 outputs a low voltage (first voltage) to the node 451 when neither of the fuses F31, F32 is disconnected, and the OR circuit 441 outputs a high voltage (second voltage) to the node 451 when at least one of the fuses F31, F32 is disconnected.

The output terminal of the OR circuit 441 is connected to the node 451. The fuse F31 is disposed between the first input terminal of the OR circuit 441 and the ground node 430. The fuse F32 is disposed between the second input terminal of the OR circuit 441 and the ground node 430.

The second adjustment circuit 432, the third adjustment circuit 433, and the fourth adjustment circuit 434 are configured similarly to the first adjustment circuit 431.

The second adjustment circuit 432 is disposed between a node 452 (first node), which is connected to the gate of transistor MN2, and the ground node 430 (second node). The second adjustment circuit 432 comprises an OR circuit 442 and a plurality of fuses F33 and F34. The OR circuit 442 outputs a voltage Vo2 depending on the disconnection state of the fuses F33 and F34. The output terminal of the OR circuit 442 is connected to the node 452. The fuse F33 is disposed between the first input terminal of the OR circuit 442 and the ground node 430. The fuse F34 is disposed between the second input terminal of the OR circuit 442 and the ground node 430.

The third adjustment circuit 433 is disposed between a node 453 (first node), which is connected to the gate of transistor MN3, and the ground node 430 (second node). The third adjustment circuit 433 comprises an OR circuit 443 and a plurality of fuses F35 and F36. The OR circuit 443 outputs a voltage Vo3 depending on the disconnection state of the fuses F35 and F36. The output terminal of the OR circuit 443 is connected to the node 453. The fuse F35 is disposed between the first input terminal of the OR circuit 443 and the ground node 430. The fuse F36 is disposed between the second input terminal of the OR circuit 443 and the ground node 430.

The fourth adjustment circuit 434 is disposed between a node 454 (first node), which is connected to the gate of transistor MN4, and the ground node 430 (second node). The fourth adjustment circuit 434 comprises an OR circuit 444 and a plurality of fuses F37 and F38. The OR circuit 444 outputs a voltage Vo4 depending on the disconnection state of the fuses F37 and F38. The output terminal of the OR circuit 444 is connected to the node 454. The fuse F37 is disposed between the first input terminal of the OR circuit 444 and the ground node 430. The fuse F38 is disposed between the second input terminal of the OR circuit 444 and the ground node 430.

The current sources 461 to 468 are disposed between one end of a corresponding fuse among the fuses F31 to F38 (the end opposite to the ground node 430) and the power supply voltage node 460.

According to the control circuit 420 according to this embodiment, for example, in the first adjustment circuit 431, when both fuses F31 and F32 are disconnected, even if the disconnection of one fuse fails, as long as the other fuse is disconnected, the OR circuit 441 can be made to output the desired voltage (high voltage).

As such, according to the control circuit 420 according to this embodiment, even if the disconnection of some of the fuses F31 and F32 fails, as long as at least one fuse is disconnected, the voltage generated by the first adjustment circuit 431 can be adjusted to the desired voltage. Therefore, by disconnecting the fuses, it becomes possible to accurately adjust the generated signal and more reliably achieve the operation of the desired circuit. Additionally, the second adjustment circuit 432, the third adjustment circuit 433, and the fourth adjustment circuit 434 can also achieve similar effects as the first adjustment circuit 431.

Furthermore, the current adjustment circuit 40 comprising the control circuit 420 and the operational amplifier including this current adjustment circuit 40 can respectively achieve effects similar to those of the current adjustment circuit 12 and the operational amplifier 1 according to the first embodiment.

Furthermore, in this embodiment, an example using an OR circuit as the signal generation circuit has been illustrated. However, the embodiment is not limited to this, and the signal generation circuit may be a circuit that operates in response to three or more input signals. For example, the signal generation circuit may be configured to output different signals when at least one of the three or more input signals is high and when all three or more input signals are low. In this case, a disconnection target element corresponding to each of the three or more input signals may be provided, and the signal input to the signal generation circuit may vary depending on the disconnection of the disconnection target elements. In this case, even if the disconnection of any of the three or more disconnection target elements fails, it becomes possible to make the signal generation circuit generate the desired signal as well.

### Application Example

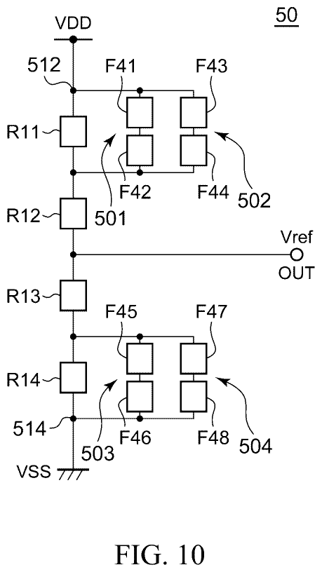

An application example of the connection paths (adjustment circuits) described in the first and second embodiments is illustrated. FIG. 10 is a circuit diagram of a voltage generation circuit 50 according to the application example. The voltage generation circuit 50 is configured to generate a reference voltage Vref. The voltage generation circuit 50 includes resistors R11 to R14, a first connection path 501, a second connection path 502, a third connection path 503, a fourth connection path 504, and an output terminal OUT.

One end of the resistor R11 is connected to a power supply voltage node 512 (second node) where the power supply voltage VDD is supplied, and the other end of the resistor R11 (first node) is connected to one end of the resistor R12. The other end of resistor R12 is connected to the output terminal OUT and one end of the resistor R13. The other end of resistor R13 is connected to one end of the resistor R14 (first node). The other end of resistor R14 is connected to a ground node 514 (second node).

The first connection path 501 and the second connection path 502 are each disposed between the other end of the resistor R11 and the power supply voltage node 512. The first connection path 501 is formed by connecting the fuses F41 and F42 in series in this order from the power supply voltage node 512 side. The second connection path 502 is formed by connecting the fuses F43 and F44 in series in this order from the power supply voltage node 512 side.

The third connection path 503 and the fourth connection path 504 are each disposed between one end of resistor R14 and the ground node 514. The third connection path 503 is formed by connecting the fuses F46 and F45 in series in this order from the ground node 514 side. The second connection path 502 is formed by connecting the fuses F48 and F47 in series in this order from the ground node 514 side.

The reference voltage Vref is adjusted by the disconnection of the fuses F41 to F48. When none of the fuses F41 to F48 are disconnected, the reference voltage Vref is VDD/2. Additionally, when all fuses F41 to F44 in the first connection path 501 and the second connection path 502 are disconnected, the reference voltage Vref becomes VDD/3. At this time, the fuses F41, F42 or the fuses F43, F44 are connected in series. Therefore, even if the disconnection of one of the fuses F41 or F42 or one of the fuses F43 or F44 fails, since the first connection path 501 and the second connection path 502 become open, the desired reference voltage (VDD/3) can be generated.

Additionally, in this application example, the first connection path 501 and the second connection path 502, or the third connection path 503 and the fourth connection path 504 are connected in parallel. Therefore, the combined resistance of the fuses F41 to F44 before disconnection and the fuses F45 to F48 before disconnection can be reduced. This application example shows an example of connecting two connection paths in parallel, but by connecting two or more connection paths in parallel, the combined resistance of the fuses can be further reduced. Additionally, instead of connecting a plurality of connection paths in parallel, a single connection path may be connected in parallel to the resistor R11 or the resistor R14.

### (Supplement)

Although the embodiments of the present disclosure have been described using specific terms, this description is merely an example to facilitate understanding and does not limit the scope of the present disclosure or the claims, and the scope of the present invention is defined by the claims. Furthermore, not only the embodiments but also other embodiments, examples, and modifications that are not described herein are included within the scope of the present invention.

One or more elements of one embodiment may be combined with one or more elements of another embodiment. For example, some of the connection paths 151 to 156 according to the first embodiment may be replaced with the adjustment circuit according to the third embodiment.

### APPENDIX

One aspect of the technology disclosed in this specification can be understood as follows.

### (Item 1)

An adjustment circuit, disposed between a first node and a second node, wherein:
the adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected.

### (Item 2)

The adjustment circuit of Item 1, wherein each of the plurality of disconnection target elements is formed of a fuse, and
the plurality of fuses are disposed side by side in a width direction of the fuse.

### (Item 3)

The adjustment circuit of Item 1 or 2, wherein the adjustment circuit is provided so that a voltage at the first node becomes a first voltage when none of the plurality of disconnection target elements are disconnected, and a voltage at the first node becomes a second voltage when at least one of the plurality of disconnection target elements is disconnected.

### (Item 4)

An adjustment circuit, disposed between a first node and a second node, wherein:
the adjustment circuit comprises a signal generation circuit and a plurality of disconnection target elements and is configured such that the signal generation circuit outputs a first voltage to the first node when none of the plurality of disconnection target elements is disconnected, and the signal generation circuit outputs a second voltage to the first node when at least one of the plurality of disconnection target elements is disconnected.

### (Item 5)

The adjustment circuit of Item 4, wherein the signal generation circuit is an OR circuit,
the plurality of disconnection target elements include a first disconnection target element and a second disconnection target element,
the first disconnection target element is disposed between a first input terminal of the OR circuit and the second node, and
the second disconnection target element is disposed between a second input terminal of the OR circuit and the second node.

### (Item 6)

A current adjustment circuit, adjusting an amount of current flowing in an active load circuit, in which the current is generated by a current generation circuit, comprising:
a sink circuit which comprises a switching element and adjusts the amount of current by sinking a current depending on whether the switching element is on or off from the current generation circuit; and
a control circuit comprising the adjustment circuit of any one of Items 3 to 5,
wherein a voltage corresponding to a voltage at the first node is input to an input terminal of the switching element,
a predetermined voltage is supplied to the second node, and
on/off of the switching element is controlled depending on whether a voltage at the first node is the first voltage or the second voltage.

### (Item 7)

An operational amplifier, including:
a current generation circuit; and
the current adjustment circuit of Item 6,
wherein the current generation circuit is an input differential pair comprising a first MOS transistor to which a first input voltage is input and a second MOS transistor to which a second input voltage is input, and
the sink circuit adjusts an amount of one of a first drain current and a second drain current flowing in the active load circuit by sinking one of the first drain current flowing in the first MOS transistor and the second drain current flowing in the second MOS transistor.

### (Item 8)

The operational amplifier of Item 7, wherein the sink circuit comprises two switching elements, one of which is a first switching element connected to a drain of the first MOS transistor and the other of which is a second switching element connected to a drain of the second MOS transistor,
the control circuit comprises a plurality of the adjustment circuits including a first adjustment circuit and a second adjustment circuit,
a voltage corresponding to a voltage at a first node of the first adjustment circuit is input to an input terminal of the first switching element,
a voltage corresponding to a voltage at a first node of the second adjustment circuit is input to an input terminal of the second switching element, and
the sink circuit sinks the first drain current or the second drain current via a switching element that is turned on among the first switching element or the second switching element.

### (Item 9)

The operational amplifier of Item 7 or 8, wherein the sink circuit includes a plurality of current paths with different current-sinking capacities, each provided with the switching element,
a voltage corresponding to a voltage at a first node of the adjustment circuit is input to an input terminal of a switching element provided in any one of the plurality of current paths, and
the sink circuit is configured to sink one of the first drain current and the second drain current via a current path in which the switching element turned on is provided among the plurality of current paths.

### (Item 10)

The operational amplifier of Item 9, wherein the switching elements have priorities defined based on the current-sinking capabilities of corresponding current paths and standard deviations of input offset voltages of the operational amplifier, and
a voltage corresponding to a voltage at a first node of the adjustment circuit is input to the input terminal of the switching element with the highest priority among the plurality of switching elements.

### (Item 11)

An adjustment method, using an adjustment circuit disposed between a first node and a second node, wherein:
the adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected, and
the adjustment method includes a disconnection step that disconnects at least one of the plurality of disconnection target elements.

### (Item 12)

The adjustment method of Item 11, wherein the plurality of disconnection target elements are each formed of a fuse,
the plurality of fuses are disposed side by side in a width direction of the fuses, and
the disconnection step includes disconnecting at least one of the plurality of disconnection target elements along a width direction of the plurality of fuses.

### (Item 13)

The adjustment method of Item 11 or 12, wherein the adjustment circuit is configured such that the first node is at a first voltage when none of the plurality of disconnection target elements are disconnected, and the first node is at a second voltage when at least one of the plurality of disconnection target elements is disconnected.

### (Item 14)

An adjustment method, using an adjustment circuit disposed between a first node and a second node, wherein:
the adjustment circuit comprises a signal generation circuit and a plurality of disconnection target elements and is configured such that the signal generation circuit outputs a first voltage to the first node when none of the plurality of disconnection target elements are disconnected, and the signal generation circuit outputs a second voltage to the first node when at least one of the plurality of disconnection target elements is disconnected, and
the adjustment method includes a disconnection step that disconnects at least one of the plurality of disconnection target elements.

### (Item 15)

A current adjustment method, adjusting an amount of current flowing in an active load circuit, in which the current is generated by a current generation circuit, using a current adjustment circuit, wherein:
the current adjustment circuit comprises:
a sink circuit which comprises a switching element and adjusts the amount of current by sinking a current from the current generation circuit depending on whether the switching element is on or off; and
a control circuit comprising the adjustment circuit of Item 13 or 14,
wherein a voltage corresponding to a voltage at the first node is input to an input terminal of the switching element,
a predetermined voltage is supplied to the second node,
on/off of the switching element is controlled depending on whether a voltage at the first node is the first voltage or the second voltage, and
the current adjustment method includes the disconnection step.

### (Item 16)

An offset adjustment method, adjusting an input offset voltage of an operational amplifier, wherein
the operational amplifier comprises:
a current generation circuit; and
the current adjustment circuit of Item 15,
wherein the current generation circuit is an input differential pair comprising a first MOS transistor to which a first input voltage is input and a second MOS transistor to which a second input voltage is input,
the sink circuit is configured to adjust an amount of one of a first drain current and a second drain current flowing in the active load circuit by sinking one of the first drain current flowing in the first MOS transistor and the second drain current flowing in the second MOS transistor, and
the offset adjustment method includes the disconnection step.

### (Item 17)

The offset adjustment method of Item 16, wherein the sink circuit comprises two switching elements, one of which is a first switching element connected to a drain of the first MOS transistor and the other of which is a second switching element connected to a drain of the second MOS transistor,
the control circuit comprises a plurality of the adjustment circuits including a first adjustment circuit and a second adjustment circuit,
a voltage corresponding to a voltage at a first node of the first adjustment circuit is input to an input terminal of the first switching element,
a voltage corresponding to a voltage at a first node of the second adjustment circuit is input to an input terminal of the second switching element,
the sink circuit is configured to sink one of the first drain current and the second drain current via a switching element that is turned on among the first switching element or the second switching element, and
the disconnection step includes disconnecting a disconnection target element that is comprised in one of the first adjustment circuit and the second adjustment circuit.

1. An adjustment circuit, disposed between a first node and a second node, wherein:
the adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected.

2. The adjustment circuit of claim 1, wherein each of the plurality of disconnection target elements is formed of a fuse, and
the plurality of fuses are disposed side by side in a width direction of the fuse.

3. The adjustment circuit of claim 1, wherein the adjustment circuit is provided so that a voltage at the first node becomes a first voltage when none of the plurality of disconnection target elements are disconnected, and a voltage at the first node becomes a second voltage when at least one of the plurality of disconnection target elements is disconnected.

4. An adjustment circuit, disposed between a first node and a second node, wherein:
the adjustment circuit comprises a signal generation circuit and a plurality of disconnection target elements and is configured such that the signal generation circuit outputs a first voltage to the first node when none of the plurality of disconnection target elements is disconnected, and the signal generation circuit outputs a second voltage to the first node when at least one of the plurality of disconnection target elements is disconnected.

5. The adjustment circuit of claim 4, wherein the signal generation circuit is an OR circuit,
the plurality of disconnection target elements include a first disconnection target element and a second disconnection target element,
the first disconnection target element is disposed between a first input terminal of the OR circuit and the second node, and
the second disconnection target element is disposed between a second input terminal of the OR circuit and the second node.

6. A current adjustment circuit, adjusting an amount of current flowing in an active load circuit, in which the current is generated by a current generation circuit, comprising:
a sink circuit which comprises a switching element and adjusts the amount of current by sinking a current depending on whether the switching element is on or off from the current generation circuit; and
a control circuit comprising the adjustment circuit of claim 3,
wherein a voltage corresponding to a voltage at the first node is input to an input terminal of the switching element,
a predetermined voltage is supplied to the second node, and
on/off of the switching element is controlled depending on whether a voltage at the first node is the first voltage or the second voltage.

7. An operational amplifier, including:
a current generation circuit; and
the current adjustment circuit of claim 6,
wherein the current generation circuit is an input differential pair comprising a first MOS transistor to which a first input voltage is input and a second MOS transistor to which a second input voltage is input, and
the sink circuit adjusts an amount of one of a first drain current and a second drain current flowing in the active load circuit by sinking one of the first drain current flowing in the first MOS transistor and the second drain current flowing in the second MOS transistor.

8. The operational amplifier of claim 7, wherein the sink circuit comprises two switching elements, one of which is a first switching element connected to a drain of the first MOS transistor and the other of which is a second switching element connected to a drain of the second MOS transistor,
the control circuit comprises a plurality of the adjustment circuits including a first adjustment circuit and a second adjustment circuit,
a voltage corresponding to a voltage at a first node of the first adjustment circuit is input to an input terminal of the first switching element,
a voltage corresponding to a voltage at a first node of the second adjustment circuit is input to an input terminal of the second switching element, and
the sink circuit sinks the first drain current or the second drain current via a switching element that is turned on among the first switching element or the second switching element.

9. The operational amplifier of claim 7, wherein the sink circuit includes a plurality of current paths with different current-sinking capacities, each provided with the switching element,
a voltage corresponding to a voltage at a first node of the adjustment circuit is input to an input terminal of a switching element provided in any one of the plurality of current paths, and
the sink circuit is configured to sink one of the first drain current and the second drain current via a current path in which the switching element turned on is provided among the plurality of current paths.

10. The operational amplifier of claim 9, wherein the switching elements have priorities defined based on the current-sinking capabilities of corresponding current paths and standard deviations of input offset voltages of the operational amplifier, and
a voltage corresponding to a voltage at a first node of the adjustment circuit is input to the input terminal of the switching element with the highest priority among the plurality of switching elements.

11. An adjustment method, using an adjustment circuit disposed between a first node and a second node, wherein:
the adjustment circuit comprises a plurality of disconnection target elements connected in series and is configured such that the first node and the second node are electrically connected via the adjustment circuit when none of the plurality of disconnection target elements are disconnected, and the adjustment circuit is open as viewed from the first node when at least one of the plurality of disconnection target elements is disconnected, and
the adjustment method includes a disconnection step that disconnects at least one of the plurality of disconnection target elements.

12. The adjustment method of claim 11, wherein the plurality of disconnection target elements are each formed of a fuse,
the plurality of fuses are disposed side by side in a width direction of the fuses, and
the disconnection step includes disconnecting at least one of the plurality of disconnection target elements along a width direction of the plurality of fuses.

13. The adjustment method of claim 11, wherein the adjustment circuit is configured such that the first node is at a first voltage when none of the plurality of disconnection target elements are disconnected, and the first node is at a second voltage when at least one of the plurality of disconnection target elements is disconnected.

14. An adjustment method, using an adjustment circuit disposed between a first node and a second node, wherein:
the adjustment circuit comprises a signal generation circuit and a plurality of disconnection target elements and is configured such that the signal generation circuit outputs a first voltage to the first node when none of the plurality of disconnection target elements are disconnected, and the signal generation circuit outputs a second voltage to the first node when at least one of the plurality of disconnection target elements is disconnected, and
the adjustment method includes a disconnection step that disconnects at least one of the plurality of disconnection target elements.

15. A current adjustment method, adjusting an amount of current flowing in an active load circuit, in which the current is generated by a current generation circuit, using a current adjustment circuit, wherein:
the current adjustment circuit comprises:
a sink circuit which comprises a switching element and adjusts the amount of current by sinking a current from the current generation circuit depending on whether the switching element is on or off; and
a control circuit comprising the adjustment circuit of claim 13,
wherein a voltage corresponding to a voltage at the first node is input to an input terminal of the switching element,
a predetermined voltage is supplied to the second node,
on/off of the switching element is controlled depending on whether a voltage at the first node is the first voltage or the second voltage, and
the current adjustment method includes the disconnection step.

16. An offset adjustment method, adjusting an input offset voltage of an operational amplifier, wherein:
the operational amplifier comprises:
a current generation circuit; and
the current adjustment circuit of claim 15,
wherein the current generation circuit is an input differential pair comprising a first MOS transistor to which a first input voltage is input and a second MOS transistor to which a second input voltage is input,
the sink circuit is configured to adjust an amount of one of a first drain current and a second drain current flowing in the active load circuit by sinking one of the first drain current flowing in the first MOS transistor and the second drain current flowing in the second MOS transistor, and
the offset adjustment method includes the disconnection step.

17. The offset adjustment method of claim 16, wherein the sink circuit comprises two switching elements, one of which is a first switching element connected to a drain of the first MOS transistor and the other of which is a second switching element connected to a drain of the second MOS transistor,
the control circuit comprises a plurality of the adjustment circuits including a first adjustment circuit and a second adjustment circuit,
a voltage corresponding to a voltage at a first node of the first adjustment circuit is input to an input terminal of the first switching element,
a voltage corresponding to a voltage at a first node of the second adjustment circuit is input to an input terminal of the second switching element,
the sink circuit is configured to sink one of the first drain current and the second drain current via a switching element that is turned on among the first switching element or the second switching element, and
the disconnection step includes disconnecting a disconnection target element that is comprised in one of the first adjustment circuit and the second adjustment circuit.
